(19) United States
(12) Patent Application Publication
(10) Pub. No.: US 2024/0332137 A1
(43) Pub. Date: Oct. 3, 2024

(54) ELECTRONIC DEVICE

(71) Applicant: ROHM CO., LTD., Kyoto-shi (JP)

(72) Inventors: Ryohei UMENO, Kyoto-shi (JP); Hiroaki MATSUBARA, Kyoto-shi (JP)

(21) Appl. No.: 18/741,266

(22) Filed: Jun. 12, 2024

Related U.S. Application Data
(63) Continuation of application No. PCT/JP2022/044721, filed on Dec. 5, 2022.

(30) Foreign Application Priority Data
Dec. 17, 2021 (JP) 2021-205191

(51) Int. Cl. H01L 23/495; H01L 23/00; H01L 25/065

(52) U.S. Cl. CPC H01L 23/49541; H01L 25/0655; H01L 24/48; H01L 2224/48137; H01L 2224/48245; H01L 2924/1424; H01L 2924/182

(57) ABSTRACT

An electronic device includes an electronic component, a sealing resin covering the electronic component, first and second terminals protruding from the sealing resin toward a first side in a first direction, and plural third terminals protruding from the sealing resin toward a second side in the first direction. The first and second terminals are located side by side with a first interval in a second direction. The third terminals are arranged in the second direction with a second interval. The first interval is greater than the second interval. Along the second direction, the first mount portion of the first terminal has a first dimension, the second mount portion of the second terminal has a second dimension, and the third mount portion of each third terminal has a third dimension. The first and second dimensions are greater than the third dimension.

### TECHNICAL FIELD

The present disclosure relates to an electronic device.

### BACKGROUND ART

In recent years, electric vehicles have become widespread. JP-A-2012-95427 discloses an example of a circuit for monitoring the voltage of a battery installed in an electric vehicle and controlling an inverter. The circuit can prevent excessive voltage from being supplied to the inverter that drives the motor.

The motor control device disclosed in JP-A-2012-95427 includes a voltage detection circuit (a high-voltage-battery voltage detection circuit) for monitoring the voltage of the battery. The voltage detection circuit may be packaged into a single electronic device and mounted on the circuit board of an electric vehicle, for example. When the small outline package (SOP) structure is employed for the packaging, a plurality of lead terminals protruding from a sealing resin are arranged at equal intervals.

### BRIEF DESCRIPTION OF THE DRAWINGS

FIG. 1 is a plan view showing an electronic device according to an embodiment.

FIG. 2 is a plan view corresponding to FIG. 1, with the sealing resin indicated by an imaginary line.

FIG. 3 is a front view showing the electronic device according to an embodiment.

FIG. 4 is a rear view showing the electronic device according to an embodiment.

FIG. 5 is a left-side view showing the electronic device according to an embodiment.

FIG. 6 is a right-side view showing the electronic device according to an embodiment.

FIG. 7 is a sectional view taken along line VII-VII in FIG. 2.

FIG. 8 is a sectional view taken along line VIII-VIII in FIG. 2.

FIG. 9 is a schematic view showing a circuit configuration of an electronic component.

FIG. 10 is a plan view showing an electronic device according to a first variation, with the sealing resin indicated by an imaginary line.

FIG. 11 is a front view showing the electronic device according to the first variation.

FIG. 12 is a plan view showing an electronic device according to a second variation, with the sealing resin indicated by an imaginary line.

FIG. 13 is a plan view showing an electronic device according to a third variation, with the sealing resin indicated by an imaginary line.

FIG. 14 is a schematic view showing a circuit configuration of an electronic component in the electronic device shown in FIG. 13.

FIG. 15 is a plan view showing an electronic device according to another mode of the third variation, with the sealing resin indicated by an imaginary line.

FIG. 16 is a plan view showing an electronic device according to a fourth variation, with the sealing resin indicated by an imaginary line.

FIG. 17 is a plan view showing an electronic device according to a fifth variation, with the sealing resin indicated by an imaginary line.

### DETAILED DESCRIPTION OF EMBODIMENTS

The following describes preferred embodiments of an electronic device of the present disclosure with reference to the drawings. Hereinafter, the same or similar elements are denoted by the same reference signs, and the descriptions thereof are omitted. In the present disclosure, the terms such as “first”, “second”, and “third” are used merely as labels and are not intended to impose ordinal requirements on the items to which these terms refer.

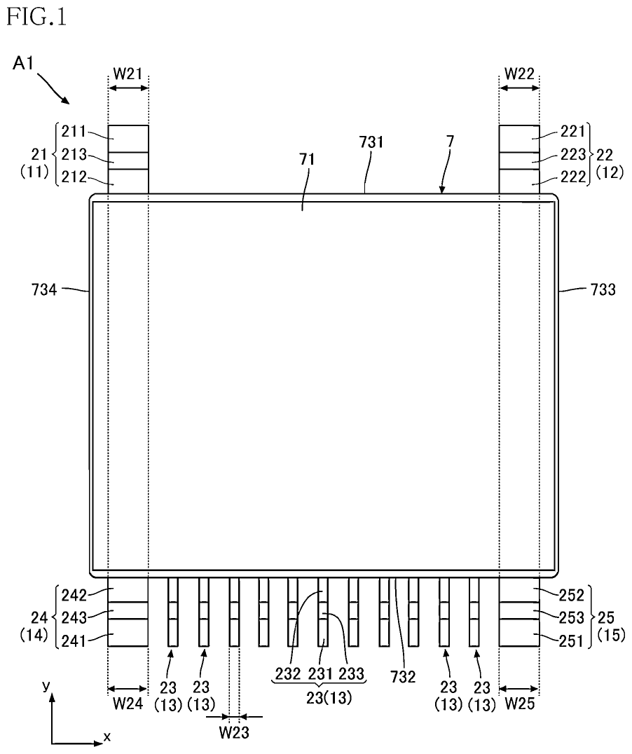

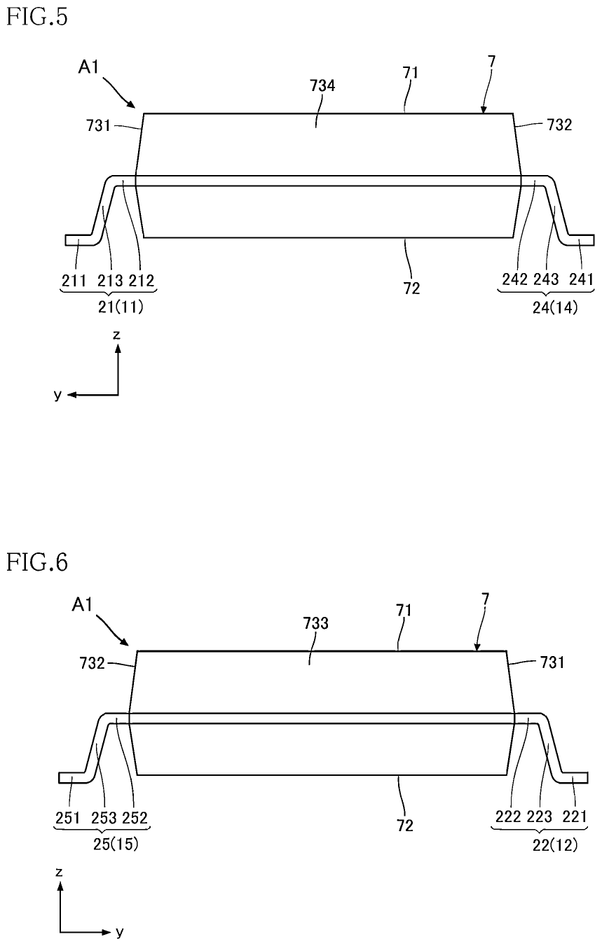

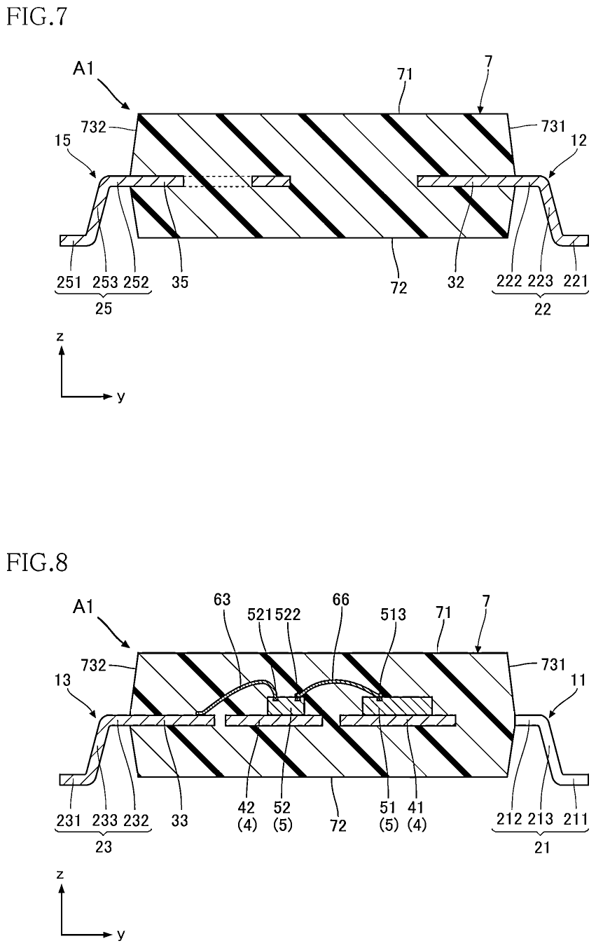

FIGS. 1 to 9 show an electronic device A1 according to an embodiment. The electronic device A1 includes a first lead 11, a second lead 12, a plurality of third leads 13, a fourth lead 14, a fifth lead 15, a die pad 4, an electronic component 5, a plurality of connecting members 61 to 66, and a sealing resin 7. The electronic device A1 includes eleven third leads 13 in the illustrated example, but the number of third leads 13 is not limited. The specific application of the electronic device A1 is not limited, and may be detection of a battery voltage in an electric vehicle, for example. The electronic device A1 may detect voltages other than the battery voltage in an electric vehicle or may detect voltages in, for example, industrial equipment, home appliances, or power supplies rather than in electric vehicles. The electronic device A1 has a surface-mount-type semiconductor package structure, which is the small outline package (SOP) structure in the present embodiment, as shown in FIGS. 1 to 8.

For the convenience of description, the thickness direction of the electronic device A1 is defined as the “thickness direction z”. In the description below, one side in the thickness direction z may be referred to as upward or upper, and the other side as downward or lower. Herein, the terms such as “top”, “bottom”, “upper”, “lower”, “upper surface”, and “lower surface” are used to indicate the relative positional relationship of parts, portions or the like in the thickness direction z and do not necessarily define the relationship with respect to the direction of gravity. Also, “plan view” refers to the view seen in the thickness direction z. A direction orthogonal to the thickness direction z is defined as the “first direction y”. The direction orthogonal to the thickness direction z and the first direction y is defined as the “second direction x”.

The first lead 11, the second lead 12, the third leads 13, the fourth lead 14, the fifth lead 15, and the die pad 4 contain a metal, such as Cu (copper), Ni (nickel), or Fe (iron), for example. The first lead 11, the second lead 12, the third leads 13, the fourth lead 14, the fifth lead 15, and the die pad 4 are obtained from a same lead frame. The first lead 11, the second lead 12, the third leads 13, the fourth lead 14, the fifth lead 15, and the die pad 4 are formed, for example, by performing working selected from punching, bending, and etching on a metal plate material. Each of the first lead 11, the second lead 12, the third leads 13, the fourth lead 14, the fifth lead 15, and the die pad 4 may be provided with a plating layer made of, for example, Ag (silver), Ni (nickel), or Au (gold) at an appropriate portion, as required.

The first lead 11, the second lead 12, the third leads 13, the fourth lead 14, and the fifth lead 15 electrically conduct to the electronic component 5 and form conduction paths in the electronic device A1. The first lead 11, the second lead 12, the third leads 13, the fourth lead 14, and the fifth lead 15 are spaced apart from each other. Each of the first lead 11, the second lead 12, the third leads 13, the fourth lead 14, and the fifth lead 15 has a portion covered with the sealing resin 7 and a portion exposed from the sealing resin 7.

The first lead 11 includes a first terminal part 21 and a first extension part 31.

The first terminal part 21 is a part of the first lead 11 that is exposed from the sealing resin 7. The first terminal part 21 protrudes from the sealing resin 7 toward a first side in the first direction y. The first terminal part 21 has a rectangular shape elongated in the first direction y in plan view. The first terminal part 21 is bent into a gull-wing shape as viewed in the second direction x. The first terminal part 21 includes a first mount portion 211, a first root portion 212, and a first intermediate portion 213.

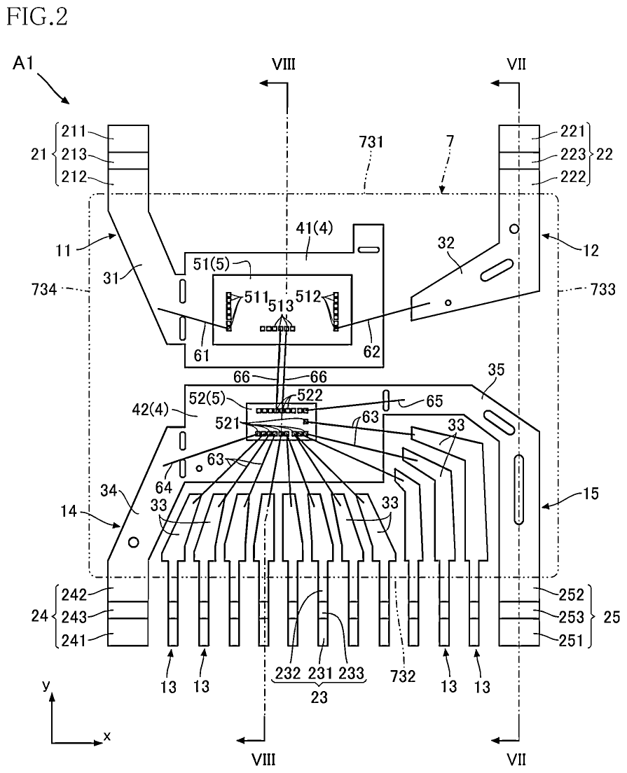

The first mount portion 211 is the extremity of the first terminal part 21. When the electronic device A1 is mounted on a circuit board of, for example, an electric vehicle, the first mount portion 211 is bonded to the circuit board. As shown in FIGS. 1 and 2, the first mount portion 211 is located at an end opposite to the sealing resin 7 in the first direction y. Thus, the first mount portion 211 is located farther from the sealing resin 7 than are the first root portion 212 and the first intermediate portion 213 in the first direction y. The first mount portion 211 is located at a lower position relative to the first root portion 212 in the thickness direction z. In the present embodiment, the first dimension W21 (see FIG. 1) along the second direction x of the first mount portion 211 is, for example, between 0.15 mm and 1.5 mm, both inclusive.

The first root portion 212 is the root part of the first terminal part 21. As shown in FIGS. 1 and 2, the first root portion 212 is located at an end closer to the sealing resin 7 of the first terminal part 21 in the first direction y. Thus, the first root portion 212 is located closer to the sealing resin 7 than are the first mount portion 211 and the first intermediate portion 213 in the first direction y. The first root portion 212 is located at an upper position relative to the first mount portion 211 in the thickness direction z and protrudes from the center in the thickness direction z of the sealing resin 7. The dimension along the second direction x of the first root portion 212 is equal to the first dimension W21 of the first mount portion 211.

The first intermediate portion 213 connects the first mount portion 211 and the first root portion 212. The first intermediate portion 213 is inclined with respect to the first mount portion 211 and the first root portion 212 as viewed along the second direction x. The dimension along the second direction x of the first intermediate portion 213 is equal to the first dimension W21 of the first mount portion 211.

The first extension part 31 is a part of the first lead 11 that is covered with the sealing resin 7. The first extension part 31 is connected to the first terminal part 21 and extends from the first terminal part 21 inward of the sealing resin 7.

The second lead 12 includes a second terminal part 22 and a second extension part 32.

The second terminal part 22 is a part of the second lead 12 that is exposed from the sealing resin 7. The second terminal part 22 protrudes from the sealing resin 7 toward the first side in the first direction y. The second terminal shape elongated in the first part 22 has a rectangular direction y in plan view. The second terminal part 22 is congruent with the first terminal part 21 in plan view in the present embodiment, but may not be congruent with the first terminal part. The second terminal part 22 is bent into a gull-wing shape as viewed in the second direction x. The second terminal part 22 overlaps with the first terminal part 21 as viewed in the second direction x. The second terminal part 22 includes a second mount portion 221, a second root portion 222, and a second intermediate portion 223.

The second mount portion 221 is the extremity of the second terminal part 22. When the electronic device A1 is mounted on a circuit board of, for example, an electric vehicle, the second mount portion 221 is bonded to the circuit board. As shown in FIGS. 1 and 2, the second mount portion 221 is located at an end opposite to the sealing resin 7 in the first direction y. Thus, the second mount portion 221 is located farther from the sealing resin 7 than are the second root portion 222 and the second intermediate portion 223 in the first direction y. The second mount portion 221 is located at a lower position relative to the second root portion 222 in the thickness direction z. The second mount portion 221 is disposed at the same position as the first mount portion 211 in the thickness direction z. In the present embodiment, the second dimension W22 (see FIG. 1) along the second direction x of the second mount portion 221 is, for example, between 0.15 mm and 1.5 mm, both inclusive. The second dimension W22 of the second mount portion 221 is equal to the first dimension W21 of the first mount portion 211 in the present embodiment, but the first dimension W21 and the second dimension W22 may differ from each other.

The second root portion 222 is the root part of the second terminal part 22. As shown in FIGS. 1 and 2, the second root portion 222 is located at an end closer to the sealing resin 7 of the second terminal part 22 in the first direction y. Thus, the second root portion 222 is located closer to the sealing resin 7 than are the second mount portion 221 and the second intermediate portion 223 in the first direction y. The second root portion 222 is located at an upper position relative to the second mount portion 221 in the thickness direction z and protrudes from the center in the thickness direction z of the sealing resin 7. The second root portion 222 is disposed at the same position as the first root portion 212 in the thickness direction z. The dimension along the second direction x of the second root portion 222 is equal to the second dimension W22 of the second mount portion 221.

The second intermediate portion 223 connects the second mount portion 221 and the second root portion 222. The second intermediate portion 223 is inclined with respect to the second mount portion 221 and the second root portion 222 as viewed along the second direction x. The dimension along the second direction x of the second intermediate portion 223 is equal to the second dimension W22 of the second mount portion 221.

The second extension part 32 is a part of the second lead 12 that is covered with the sealing resin 7. The second extension part 32 is connected to the second terminal part 22 and extends from the second terminal part 22 inward of the sealing resin 7.

Each of the third leads 13 includes a third terminal part 23 and a third extension part 33. Therefore, the electronic device A1 includes a plurality of third terminal parts 23 and a plurality of third extension parts 33. The third terminal part 23 and the third extension part 33 described below are common to all third leads 13 unless otherwise specifically noted.

The third terminal part 23 is a part of a third lead 13 that is exposed from the sealing resin 7. Each third terminal part 23 protrudes from the sealing resin 7 toward a second side in the first direction y. Each third terminal part 23 has the shape of a strip elongated in the first direction y in plan view. The third terminal parts 23 are arranged at equal intervals along the second direction x. Each third terminal part 23 is bent into a gull-wing shape as viewed in the second direction x. The third terminal parts 23 overlap with each other as viewed in the second direction x. Each third terminal part 23 includes a third mount portion 231, a third root portion 232, and a third intermediate portion 233. Therefore, the electronic device A1 includes a plurality of third mount portions 231, a plurality of third root portions 232, and a plurality of third intermediate portions 233. The third mount portion 231, the third root portion 232, and the third intermediate portion 233 described below are common to all third terminal parts 23 unless otherwise specifically noted.

The third mount portion 231 is the extremity of a third terminal part 23. When the electronic device A1 is mounted on a circuit board of, for example, an electric vehicle, the third mount portion 231 is bonded to the circuit board. As shown in FIGS. 1 and 2, the third mount portion 231 is located at an end opposite to the sealing resin 7 in the first direction y. Thus, the third mount portion 231 is located farther from the sealing resin 7 than are the third root portion 232 and the third intermediate portion 233 in the first direction y. The third mount portion 231 is located at a lower position relative to the third root portion 232 in the thickness direction z. The plurality of third mount portions 231 are disposed at the same position in the thickness direction z. The third dimension W23 (see FIG. 1) in the second direction x of each third mount portion 231 is smaller than each of the first dimension W21 of the first mount portion 211 and the second dimension W22 of the second mount portion 221. For example, each of the first dimension W21 of the first mount portion 211 and the second dimension W22 of the second mount portion 221 is 1 to 10 times the third dimension W23 of each third mount portion 231. In the present embodiment, the third dimension W23 in the second direction x of each third mount portion 231 is, for example, between 0.15 mm and 0.5 mm, both inclusive.

The third root portion 232 is the root part of the third terminal part 23. As shown in FIGS. 1 and 2, the third root portion 232 is located at an end closer to the sealing resin 7 of the third terminal part 23 in the first direction y. Thus, the third root portion 232 is located closer to the sealing resin 7 than are the third mount portion 231 and the third intermediate portion 233 in the first direction y. The third root portion 232 is located at an upper position relative to the third mount portion 231 in the thickness direction z and protrudes from the center in the thickness direction z of the sealing resin 7. The plurality of third root portions 232 are disposed at the same position in the thickness direction z. The dimension along the second direction x of the third root portion 232 is equal to the third dimension W23 of the third mount portion 231.

The third intermediate portion 233 connects the third mount portion 231 and the third root portion 232. The third intermediate portion 233 is inclined with respect to the third mount portion 231 and the third root portion 232 as viewed along the second direction x. The dimension along the second direction x of the third intermediate portion 233 is equal to the third dimension W23 of the third mount portion 231.

The third extension part 33 is a part of a third lead 13 that is covered with the sealing resin 7. The third extension part 33 is connected to the third terminal part 23 and extends from the third terminal part 23 inward of the sealing resin 7.

The fourth lead 14 includes a fourth terminal part 24 and a fourth extension part 34.

The fourth terminal part 24 is a part of the fourth lead 14 that is exposed from the sealing resin 7. The fourth terminal part 24 protrudes from the sealing resin 7 toward the second side in the first direction y. The fourth terminal part 24 has a rectangular shape elongated in the first direction y in plan view. The fourth terminal part 24 is congruent with the first terminal part 21 in plan view in the present embodiment, but may not be congruent with the first terminal part. The fourth terminal part 24 is located on a second side in the second direction x with respect to the third terminal parts 23. The fourth terminal part 24 is bent into a gull-wing shape as viewed in the second direction x. The fourth terminal part 24 overlaps with each third terminal part 23 as viewed in the second direction x. The fourth terminal part 24 overlaps with the first terminal part 21 as viewed along the first direction y. The fourth terminal part 24 includes a fourth mount portion 241, a fourth root portion 242, and a fourth intermediate portion 243.

The fourth mount portion 241 is the extremity of the fourth terminal part 24. When the electronic device A1 is mounted on a circuit board of, for example, an electric vehicle, the fourth mount portion 241 is bonded to the circuit board. As shown in FIGS. 1 and 2, the fourth mount portion 241 is located at an end opposite to the sealing resin 7 in the first direction y. Thus, the fourth mount portion 241 is located farther from the sealing resin 7 than are the fourth root portion 242 and the fourth intermediate portion 243 in the first direction y. The fourth mount portion 241 is located at a lower position relative to the fourth root portion 242 in the thickness direction z. The fourth mount portion 241 is disposed at the same position as each third mount portion 231 in the thickness direction z. In the present embodiment, the fourth dimension W24 (see FIG. 1) along the second direction x of the fourth mount portion 241 is, for example, between 0.15 mm and 1.5 mm, both inclusive. In the present embodiment, the fourth dimension W24 of the fourth mount portion 241 is equal to the first dimension W21 of the first mount portion 211.

The fourth root portion 242 is the root part of the fourth terminal part 24. As shown in FIGS. 1 and 2, the fourth root portion 242 is located at an end closer to the sealing resin 7 of the fourth terminal part 24 in the first direction y. Thus, the fourth root portion 242 is located closer to the sealing resin 7 than are the fourth mount portion 241 and the fourth intermediate portion 243 in the first direction y. The fourth root portion 242 is located at an upper position relative to the fourth mount portion 241 in the thickness direction z and protrudes from the center in the thickness direction z of the sealing resin 7. The fourth root portion 242 is disposed at the same position as each third root portion 232 in the thickness direction z. The dimension along the second direction x of the fourth root portion 242 is equal to the fourth dimension W24 of the fourth mount portion 241.

The fourth intermediate portion 243 connects the fourth mount portion 241 and the fourth root portion 242. The fourth intermediate portion 243 is inclined with respect to the fourth mount portion 241 and the fourth root portion 242 as viewed along the second direction x. The dimension along the second direction x of the fourth intermediate portion 243 is equal to the fourth dimension W24 of the fourth mount portion 241.

The fourth extension part 34 is a part of the fourth lead 14 that is covered with the sealing resin 7. The fourth extension part 34 is connected to the fourth terminal part 24 and extends from the fourth terminal part 24 inward of the sealing resin 7.

The fifth lead 15 includes a fifth terminal part 25 and a fifth extension part 35.

The fifth terminal part 25 is a part of the fifth lead 15 that is exposed from the sealing resin 7. As shown in FIG. 2, the fifth terminal part 25 protrudes from the sealing resin 7 toward the second side in the first direction y. The fifth terminal part 25 has a rectangular shape elongated in the first direction y in plan view. The fifth terminal part 25 is congruent with the second terminal part 22 in plan view in the present embodiment, but may not be congruent with the second terminal part. Also, the fifth terminal part 25 is congruent with the fourth terminal part 24 in plan view in the present embodiment, but may not be congruent with the fourth terminal part. The fifth terminal part 25 is located on the first side in the second direction x with respect to the third terminal parts 23. That is, the fifth terminal part 25 is located opposite to the fourth terminal part 24 in the second direction x with respect to the third terminal parts 23. The fifth terminal part 25 is bent into a gull-wing shape as viewed in the second direction x. The fifth terminal part 25 overlaps with each third terminal part 23 as viewed in the second direction x. The fifth terminal part 25 overlaps with the second terminal part 22 as viewed along the first direction y. The fifth terminal part 25 includes a fifth mount portion 251, a fifth root portion 252, and a fifth intermediate portion 253.

The fifth mount portion 251 is the extremity of the fifth terminal part 25. When the electronic device A1 is mounted on a circuit board of, for example, an electric vehicle, the fifth mount portion 251 is bonded to the circuit board. In FIGS. 1 and 2, the fifth mount portion 251 is located at an end opposite to the sealing resin 7 in the first direction y. Thus, the fifth mount portion 251 is located farther from the sealing resin 7 than are the fifth root portion 252 and the fifth intermediate portion 253 in the first direction y. The fifth mount portion 251 is located at a lower position relative to the in the thickness direction z. The fifth mount portion 251 is disposed at the same position as each third mount portion 231 in the thickness direction z. In the present embodiment, the fifth dimension W25 (see FIG. 1) along the second direction x of the fifth mount portion 251 is, for example, between 0.15 mm and 1.5 mm, both inclusive. In the present embodiment, the fifth dimension W25 of the fifth mount portion 251 is equal to the second dimension W22 of the second mount portion 221.

The fifth root portion 252 is the root part of the fifth terminal part 25. As shown in FIGS. 1 and 2, the fifth root portion 252 is located at an end closer to the sealing resin 7 of the fifth terminal part 25 in the first direction y. Thus, the fifth root portion 252 is located closer to the sealing resin 7 than are the fifth mount portion 251 and the fifth intermediate portion 253 in the first direction y. The fifth root portion 252 is located at an upper position relative to the fifth mount portion 251 in the thickness direction z and protrudes from the center in the thickness direction z of the sealing resin 7. The fifth root portion 252 is disposed at the same position as each third root portion 232 in the thickness direction z. The dimension along the second direction x of the fifth root portion 252 is equal to the fifth dimension W25 of the fifth mount portion 251.

The fifth intermediate portion 253 connects the fifth mount portion 251 and the fifth root portion 252. The fifth intermediate portion 253 is inclined with respect to the fifth mount portion 251 and the fifth root portion 252 as viewed along the second direction x. The dimension along the second direction x of the fifth intermediate portion 253 is equal to the fifth dimension W25 of the fifth mount portion 251.

The fifth extension part 35 is a part of the fifth lead 15 that is covered with the sealing resin 7. The fifth extension part 35 is connected to the fifth terminal part 25 and extends from the fifth terminal part 25 inward of the sealing resin 7. The third extension parts 33 are located between the fourth extension part 34 and the fifth extension part 35 in the second direction x.

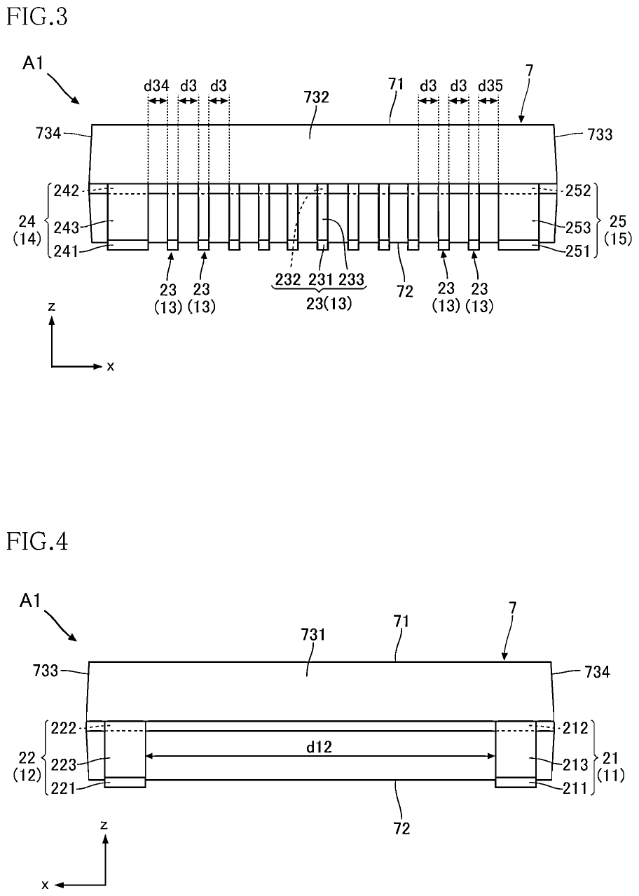

In the electronic device A1, the first mount portion 211 and the second mount portion 221 are located side by side with a first interval d12 (see FIG. 4) in the second direction x. The plurality of third mount portions 231 are arranged in the second direction x with a second interval d3 (see FIG. 3). The first interval d12 (see FIG. 4) between the first mount portion 211 and the second mount portion 221 in the second direction x is greater than the second interval d3 (see FIG. 3) between adjacent third mount portions 231 in the second direction x. For example, the first interval d12 is 10 to 20 times the second interval d3. In the present embodiment, the first interval d12 is, for example, between 5 mm and 10 mm, both inclusive, and the second interval d3 is, for example, between 0.25 mm and 5 mm, both inclusive. When the potential difference between the first mount portion 211 and the second mount portion 221 is about 800 V, the first interval d12 is preferably 4 mm or greater. The third interval d34 (see FIG. 3) between the fourth mount portion 241 and the third mount portion 231 adjacent to the fourth mount portion 241 in the second direction x is equal to the second interval d3. Also, the fourth interval d35 (see FIG. 3) between the fifth mount portion 251 and the third mount portion 231 adjacent to the fifth mount portion 251 in the second direction x is equal to the second interval d3.

In one example, in the electronic device A1, each of the first dimension W21 of the first mount portion 211, the second dimension W22 of the second mount portion 221, the fourth dimension W24 of the fourth mount portion 241, and the fifth dimension W25 of the two fifth mount portion 251 is equal to the sum of the third dimensions W23 of the two third mount portions 231 and the interval d2 (W23×2+d3).

In the electronic device A1, the first terminal part 21, the second terminal part 22, the third terminal parts 23, the fourth terminal part 24, and the fifth terminal part 25 are outer leads, while the first extension part 31, the second extension part 32, the third extension parts 33, the fourth extension part 34, and the fifth extension part 35 are inner leads. In the electronic device of the present disclosure, the shape of the inner leads is not limited to the illustrated example.

The die pad 4 supports the electronic component 5. The die pad 4 includes a first pad part 41 and a second pad part 42. The first pad part 41 and the second pad part 42 are spaced apart from each other. The shape in plan view of the first pad part 41 and the second pad part 42 are not limited, but rectangular in the illustrated example. As shown in FIG. 2, the first pad part 41 and the second pad part 42 are, for example, aligned in the first direction y, with the first pad part 41 located on the first side in the first direction y from the second pad part 42. As shown in FIG. 2, the first pad part 41 is connected to the first extension part 31. The first pad part 41 and the first lead 11 are integrally formed. The second pad part 42 is connected to the fourth extension part 34 and the fifth extension part 35. The second pad part 42 is integrally formed with the fourth lead 14 and the fifth lead 15.

In the electronic device A1, the shapes and positional relationship of the die pad 4 and the above-described inner leads (the first extension part 31, the second extension part 32, the third extension parts 33, the fourth extension part 34, and the fifth extension part 35) are not limited to the illustrated example, and can be varied as appropriate depending on the specifications of the electronic device A1. The electronic component 5 is an element that exerts an electrical function of the electronic device A1. The specific function of the electronic component 5 is not limited, but in the present embodiment, the electronic component 5 has the function of detecting voltage. In the illustrated example, the electronic component 5 includes a first chip 51 and a second chip 52 separated from each other.

The first chip 51 is mounted on the first pad part 41. In the present embodiment, the first chip 51 outputs a first signal corresponding to the potential at the first lead 11 and a second signal corresponding to the potential at the second lead 12 to the second chip 52. The first chip 51 has a plurality of electrodes 511, 512 and 513 on the upper surface in the thickness direction z.

The second chip 52 is mounted on the second pad part 42. In the present embodiment, the second chip 52 receives the first signal and the second signal from the first chip 51 and outputs a third signal corresponding to the potential difference between the first lead 11 and the second lead 12. That is, the second chip 52 outputs a detection signal (third signal) of the voltage applied between the first lead 11 and the second lead 12. The second chip 52 has a plurality of electrodes 521 and 522 on the upper surface in the thickness direction z.

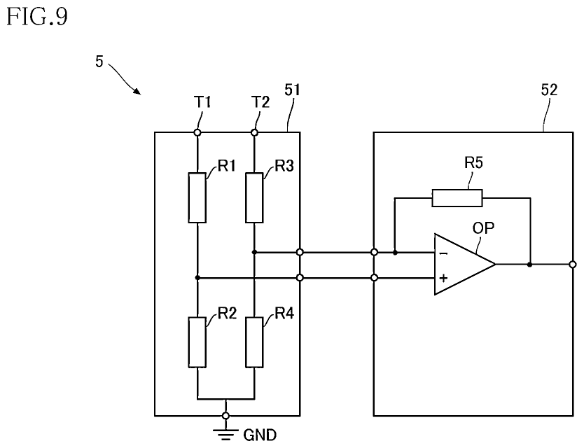

In the electronic device A1, the electronic component 5 (the first chip 51 and the second chip 52) has the circuit configuration shown in FIG. 9, for example. As shown in FIG. 9, the first chip 51 includes a plurality of resistor elements R1 to R4, and the second chip 52 includes an operational amplifier OP and a resistor element R5. The circuit configuration of the electronic component 5 shown in FIG. 9 is not limited to the example shown in FIG. 9.

The two resistor elements R1 and R2 are connected in series to each other. The two resistor elements R1 and R2 divide the voltage at the terminal T1 (the potential difference between the potential at the terminal T1 and the reference potential at the ground GND). In the present embodiment, the terminal T1 corresponds to each electrode 512. The connection point between the two resistor elements R1 and R2 is connected to the non-inverting input terminal of the operational amplifier OP. The two resistor elements R3 and R4 are connected in series to each other. The two resistor elements R3 and R4 divide the voltage at the terminal T2 (the potential difference between the potential at the terminal T2 and the reference potential at the ground GND). In the present embodiment, the terminal T2 corresponds to each electrode 511. The connection point between the two resistor elements R3 and R4 is connected to the inverting input terminal of the operational amplifier OP. When the electronic device A1 detects the voltage of a battery installed in an electric vehicle, one of the terminals T1 and T2 is electrically connected to the high-potential-side terminal of the battery, while the other is electrically connected to the low-potential-side terminal of the battery.

The operational amplifier OP receives the first signal corresponding to the potential at the terminal T1 (a signal obtained by dividing the voltage of the terminal T1 in the present embodiment) and the second signal corresponding to the potential at the terminal T2 (a signal obtained by dividing the voltage of the terminal T2 in the present embodiment), and outputs a third signal corresponding to the potential difference between the terminal T1 and the terminal T2. The resistor element R5 is an element (feedback resistor) for determining the amplification gain of the operational amplifier OP. One end of the resistor element R5 is connected to the inverting input terminal of the operational amplifier OP, and the other end is connected to the output terminal of the operational amplifier OP. Incidentally, the second chip 52 may not include the resistor element R5.

Each of the connecting members 61 to 66 electrically connects mutually separated parts to each other. In the illustrated example, each of the connecting members 61 to 66 is a bonding wire. Each of the connecting members 61 to 66 may be a metal plate rather than a bonding wire. Each connecting member 61 to 66 contains one of Au, A1 (aluminum), and Cu.

As shown in FIG. 2, the connecting member 61 is bonded to the electrode 511 of the first chip 51 and the first extension part 31 to electrically connect the first chip 51 and the first lead 11. That is, the first terminal part 21 of the first lead 11 electrically conducts to the first chip 51 of the electronic component 5 via the connecting member 61.

As shown in FIG. 2, the connecting member 62 is bonded to the electrode 512 of the first chip 51 and the second extension part 32 to electrically connect the first chip 51 and the second lead 12. That is, the second terminal part 22 of the second lead 12 electrically conducts to the first chip 51 of the electronic component 5 via the connecting member 62.

As shown in FIG. 2, each of the connecting members 63 is bonded to the electrode 521 of the second chip 52 and one of the third extension parts 33 to electrically connect the second chip 52 and one of the third leads 13. That is, the third terminal part 23 of each third lead 13 electrically conducts to the second chip 52 of the electronic component 5 via one of the connecting members 63.

As shown in FIG. 2, the connecting member 64 is bonded to the electrode 521 of the second chip 52 and the fourth extension part 34 to electrically connect the second chip 52 and the fourth lead 14. That is, the fourth terminal part 24 of the fourth lead 14 electrically conducts to the second chip 52 of the electronic component 5 via the connecting member 64.

As shown in FIG. 2, the connecting member 65 is bonded to the electrode 521 of the second chip 52 and the fifth extension part 35 to electrically connect the second chip 52 and the fifth lead 15. That is, the fifth terminal part 25 of the fifth lead 15 electrically conducts to the second chip 52 of the electronic component 5 via the connecting member 65.

As shown in FIG. 2, the connecting members 66 are bonded to the electrode 513 of the first chip 51 and the electrode 522 of the second chip 52 to electrically connect the first chip 51 and the second chip 52. Thus, the connecting members 66 are transmission paths for the first signal and the second signal described above.

The sealing resin 7 covers a part of each of the first lead 11, the second lead 12, the third leads 13, the fourth lead 14 and the fifth lead 15, as well as the die pad 4 (the first pad part 41 and the second pad part 42), the electronic component 5 (the first chip 51 and the second chip 52), and the connecting members 61 to 66. The sealing resin 7 includes an insulating material, such as an epoxy resin, for example. Preferably, the sealing resin 7 is made of a resin material with a CTI (Comparative Tracking Index) of 600V or higher. The sealing resin 7 is, for example, in the shape of a rectangular parallelepiped. The sealing resin 7 is, for example, between 5 mm and 15 mm, both inclusive, in dimension along the second direction x and between 3 mm and 13 mm, both inclusive, in dimension along the first direction y. The sealing resin 7 has a resin obverse surface 71, a resin reverse surface 72, and a plurality of resin side surfaces 731 to 734.

The resin obverse surface 71 and the resin reverse surface 72 are spaced apart from each other in the thickness direction z. The resin obverse surface 71 faces one side in the thickness direction z and the resin reverse surface 72 faces the other side in the thickness direction z. The resin obverse surface 71 is the upper surface of the sealing resin 7, and the resin reverse surface 72 is the lower surface of the sealing resin 7.

The pair of resin side surfaces 731 and 732 are spaced apart from each other in the first direction y. The resin side surface 731 faces the first side in the first direction y, and the resin side surface 732 faces the second side in the first direction y. The pair of resin side surfaces 733 and 734 are spaced apart from each other in the second direction x. The resin side surface 733 faces the first side in the second direction x, and the resin side surface 734 faces the second side in the second direction x.

As shown in FIGS. 1, 2, and 4 to 6, the first terminal part 21 and the second terminal part 22 protrude from the resin side surface 731. As shown in FIGS. 1 to 3, 5, and 6, the third terminal parts 23, the fourth terminal part 24, and the fifth terminal part 25 protrude from f the resin side surface 732.

The effects of the electronic device A1 are as follows.

In the electronic device A1, the first terminal part 21 and the second terminal part 22 are located side by side with the first interval d12 in the second direction x, and the plurality of third terminal parts 23 are arranged in the second direction x with the second interval d3. The first interval d12 is greater than the second interval d3. With such a configuration, the creepage distance (the distance along the surface of the sealing resin 7) between the first terminal part 21 and the second terminal part 22 is greater than the creepage distance (the distance along the surface of the sealing resin 7) between adjacent third terminal parts 23. Therefore, electric discharge between the first terminal part 21 and the second terminal part 22 is less likely to occur when a high voltage is applied between the first terminal part 21 and the second terminal part 22. Thus, the electronic device A1 is capable of suppressing electric discharge between the first terminal part 21 and the second terminal part 22 while achieving downsizing of the device. In other words, the electronic package structure favorable for suppressing electric discharge between the first terminal part 21 and the second terminal part 22.

In the electronic device A1, the first dimension W21 along the second direction x of the first mount portion 211 and the second dimension W22 along the second direction x of the second mount portion 221 are each greater than the third dimension W23 along the second direction x of each third mount portion 231. When the electronic device A1 is mounted on a circuit board of, for example, an electric vehicle, thermal stress due to heat from the electric vehicle is applied to each of the first mount portion 211, the second mount portion 221, and each third mount portion 231. As shown in FIGS. 1 and 2, the number of lead terminals (the first terminal part 21 and the second terminal part 22) protruding from the first side in the first direction y of the sealing resin 7 is smaller than the number of lead terminals (the third terminal parts 23) protruding from the second side in the first direction y of the sealing resin 7. With such a configuration, the imbalance in the number of lead terminals between the first side and the second side in the first direction y of the sealing resin 7 results in the thermal stress concentrating on the lead terminals (the first terminal part 21 and the second terminal part 22) protruding from the first side in the first direction y of the sealing resin 7. Such concentration of thermal stress can cause the first terminal part 21 and the second terminal part 22 to separate from the circuit board. In the electronic device A1, by making the first dimension W21, the second dimension W22, and the third dimension W23 have the above-described relationship, thermal stress applied to the first terminal part 21 and the second terminal part 22 can be relieved as compared with the case where the first dimension W21 and the second dimension W22 are equal to the third dimension W23. Thus, the electronic device A1 is capable of preventing the first terminal part 21 and the second terminal part 22 from separating from the circuit board of an electric vehicle or other device, and hence improving the mounting reliability of the device.

The electronic device A1 includes the fourth mount portion 241 overlapping with the first mount portion as viewed in the first direction y, and the fifth mount portion 251 overlapping with the second mount portion 221 as viewed in the first direction y. The fourth dimension W24 along the second direction x of the fourth mount portion 241 is equal to the first dimension W21 of the first mount portion 211, and the fifth dimension W25 along the second direction x of the fifth mount portion 251 is equal to the second dimension W22 of the second mount portion 221. Such a configuration equalizes the thermal stress applied to the first mount portion 211 and the thermal stress applied to the fourth mount portion 241, while also equalizing the thermal stress applied to the second mount portion 221 and the thermal stress applied to the fifth mount portion 251. In particular, when the first dimension W21 of the first mount portion 211 and the second dimension W22 of the second mount portion 221 are equal to each other, it is possible to equalize the thermal stress applied to respective lead terminals (the first terminal part 21, the second terminal part 22, the fourth terminal part 24, the fifth terminal part 25) disposed at the four corners of the electronic device A1. Thus, the electronic device A1 can further improve the mounting reliability of the lead terminals disposed at the four corners.

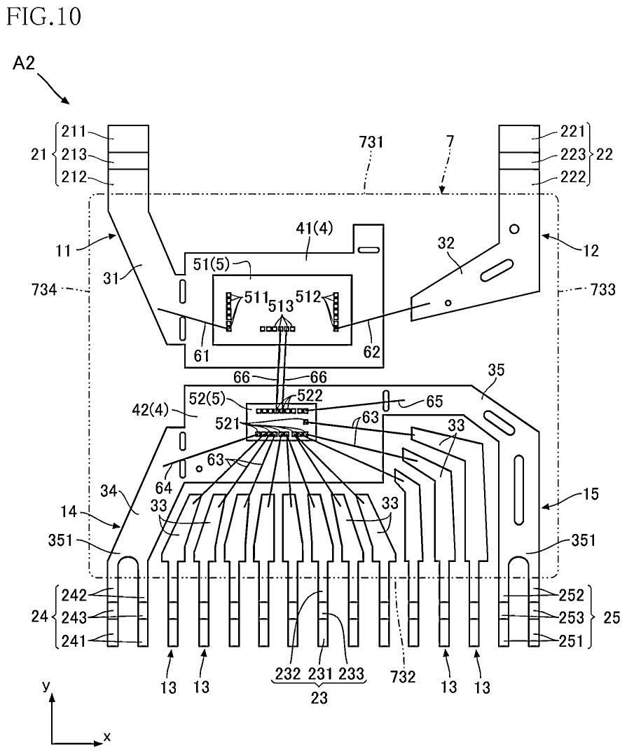

Next, electronic devices according to variations of the present disclosure will be described with reference to FIGS. 10 to 17. Various parts of the variations may be selectively used in any appropriate combination as long as it is technically compatible.

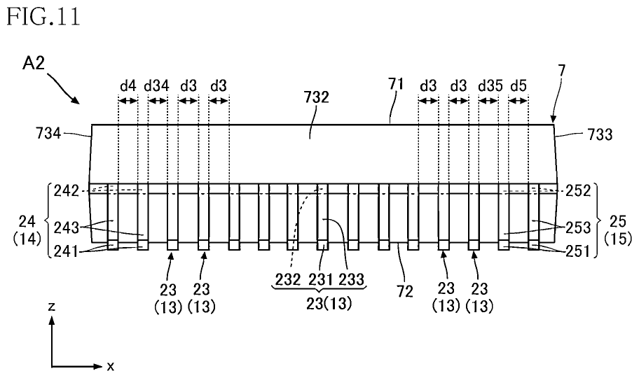

FIGS. 10 and 11 show an electronic device A2 according to a first variation. As shown in FIGS. 10 and 11, the electronic device A2 differs from the electronic device A1 in configurations of the fourth lead 14 and the fifth lead 15.

In the fourth lead 14 of the electronic device A2, the fourth terminal part 24 includes a plurality of mutually separated sections, and each of such sections includes fourth mount portion 241, a fourth root portion 242, and a fourth intermediate portion 243. In the example shown in FIGS. 10 and 11, the fourth terminal part 24 includes two mutually separated sections, and the fourth terminal part 24 includes two fourth mount portions 241, two fourth root portions 242, and two fourth intermediate portions 243.

The two fourth mount portions 241 are located side by side in the second direction x on the second side in the second direction x (the left side in FIG. 10) of the third mount portions 231. The fourth dimension W24 along the second direction x of each fourth mount portion 241 is equal to the third dimension W23 of each third mount portion 231. The interval d4 between the two fourth mount portions 241 is equal to the interval d3 between adjacent third mount portions 231 in the second direction x. As viewed in the first direction y, one of the two fourth mount portions 241 that is located on the second side in the second direction x (the left side in FIG. 10) and the first mount portion 211 overlap with each other at respective edges on the second side in the second direction x. As viewed in the first direction y, one of the two fourth mount portions 241 that is located on the first side in the second direction x (the right side in FIG. 10) and the first mount portion 211 overlap with each other at respective edges on the first side in the second direction x.

Each of the two fourth root portions 242 is a part of the fourth terminal part 24 that is located at an end closer to the sealing resin 7 in the first direction y.

One of the two fourth intermediate portions 243 connects one of the two fourth mount portions 241 and one of the two fourth root portions 242. The other one of the two fourth intermediate portions 243 connects the other one of the two fourth mount portions 241 and the other one of the two fourth root portions 242.

The dimension along the second direction x of each of the two fourth root portions 242 and each of the two fourth intermediate portions 243 is equal to the fourth dimension W24 of each fourth mount portion 241.

In the fourth lead 14 of the electronic device A2, the fourth extension part 34 includes a branching portion 341. The branching portion 341 is located at the end of the fourth extension part 34 that is connected to the fourth terminal part 24. In a configuration where the fourth terminal part 24 includes two fourth root portions 242, the branching portion 341 is bifurcated. The two fourth root portions 242 extend from the branched extremities of the branching portion 341. Thus, the two fourth mount portions 241 of the fourth terminal part 24 will have the same potential.

In the fifth lead 15 of the electronic device A2, the fifth terminal part 25 includes a plurality of mutually separated sections, and each of such sections includes a fifth mount portion 251, a fifth root portion 252, and a fifth intermediate portion 253. In the example shown in FIGS. 10 and 11, the fifth terminal part 25 includes two mutually separated sections, and the fifth terminal part 25 includes two fifth mount portions 251, two fifth root portions 252, and two fifth intermediate portions 253.

The two fifth mount portions 251 are located side by side in the second direction x on the first side in the second direction x (the right side in FIG. 10) of the third mount portions 231. The fifth dimension W25 along the second direction x of each fifth mount portion 251 is equal to the third dimension W23 of each third mount portion 231. The interval d5 between the two fifth mount portions 251 is equal to the interval d3 between adjacent third mount portions 231 in the second direction x. As viewed in the first direction y, one of the two fifth mount portions 251 that is located on the first side in the second direction x (the right side in FIG. 10) and the second mount portion 221 overlap with each other at respective edges on the first side in the second direction x. As viewed in the first direction y, one of the two fifth mount portions 251 that is located on the second side in the second direction x (the left side in FIG. 10) and the second mount portion 221 overlap with each other at respective edges on the second side in the second direction X.

Each of the two fifth root portions 252 is a part of the fifth terminal part 25 that is located at an end closer to the sealing resin 7 in the first direction y.

One of the two fifth intermediate portions 253 connects one of the two fifth mount portions 251 and one of the two fifth root portions 252. The other one of the two fifth intermediate portions 253 connects the other one of the two fifth mount portions 251 and the other one of the two fifth root portions 252.

The dimension along the second direction x of each of the two fifth root portions 252 and each of the two fifth intermediate portions 253 is equal to the fifth dimension W25 of each fifth mount portion 251.

In the fifth lead 15 of the electronic device A2, the fifth extension part 35 includes a branching portion 351. The branching portion 351 is located at the end of the fifth extension part 35 that is connected to the fifth terminal part 25. In a configuration where the fifth terminal part 25 includes two fifth root portions 252, the branching portion 351 is bifurcated. The two fifth root portions 252 extend from the branched extremities of the branching portion 351. Thus, the two fifth mount portions 251 of the fifth terminal part 25 will have the same potential.

As with the electronic devices A1, the electronic device A2 is capable of suppressing electric discharge between the first terminal part 21 and the second terminal part 22 while achieving downsizing of the device. Also, as with the electronic device A1, the electronic device A2 is capable of relieving the stress applied to the first terminal part 21 and the second terminal part 22, thereby improving the mounting reliability of the device.

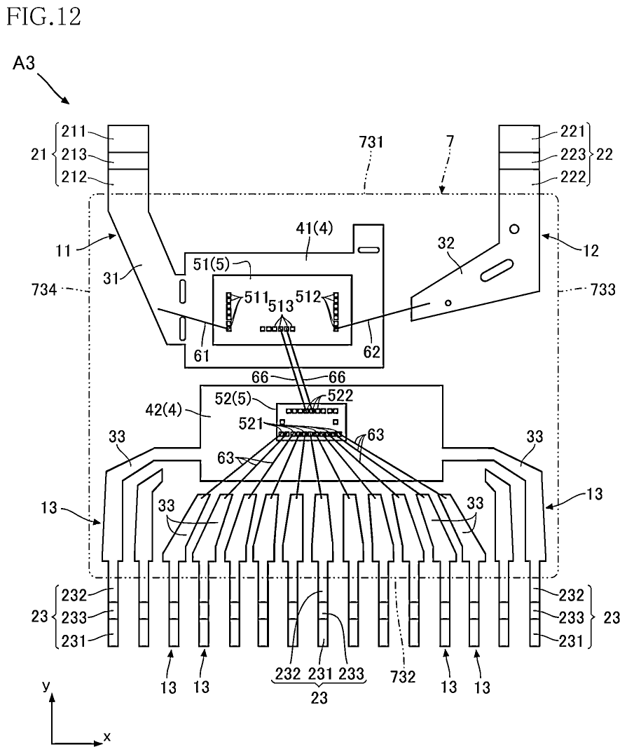

FIG. 12 shows an electronic device A3 according to a second variation. The electronic device A3 differs from the electronic device A1 in that it does not include either the fourth lead 14 or the fifth lead 15.

The appearance of the electronic A3 device is substantially the same as that of the electronic device A2.

In the electronic device A3, however, the outermost third leads 13 on each side in the second direction x are connected to the second pad part 42.

As with the electronic devices A1, the electronic device A3 is capable of suppressing electric discharge between the first terminal part 21 and the second terminal part 22 while achieving downsizing of the device. Also, as with the electronic device A1, the electronic device A3 is capable of relieving the stress applied to the first terminal part 21 and the second terminal part 22, thereby improving the mounting reliability of the device.

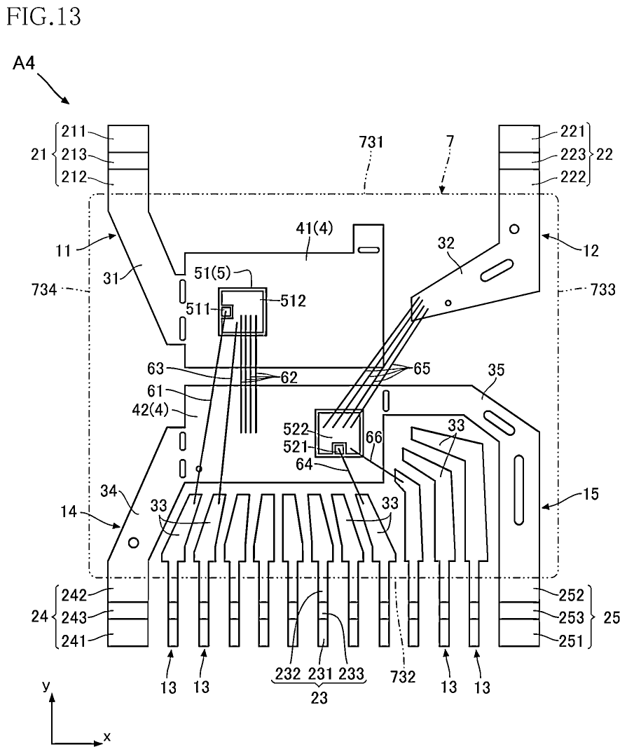

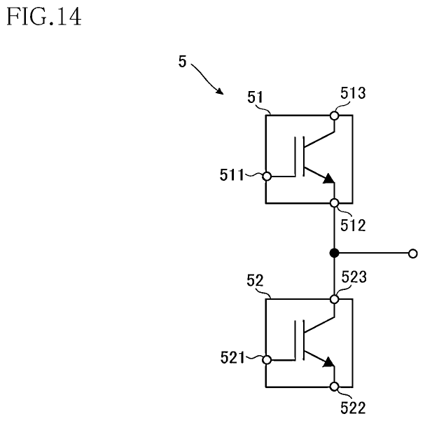

FIGS. 13 and 14 show an electronic device A4 according to a third variation. The electronic device A4 differs from the electronic device A1 in function of the electronic component 5.

The electronic component 5 of the electronic device A4 has a power conversion function rather than a voltage detection function. Each of the first chip 51 and the second chip 52 is a switching element. Although the circuit diagram in FIG. 14 shows an example in which each of the first chip 51 and the second chip 52 is an IGBT (Insulated Gate Bipolar Transistor), these chips may not be IGBTs but may be other transistors, such as MOSFETs (Metal-Oxide-Semiconductor Field Effect Transistor) or bipolar transistors.

As shown in FIG. 14, the first chip 51 has three electrodes 511, 512 and 513. In the example in which the first chip 51 is an IGBT, the electrode 511 is a gate, the electrode 512 is an emitter, and the electrode 513 is a collector. The first chip 51 is configured, for example, as a vertical structure type, with two electrodes 511 and 512 disposed on the upper surface (the surface facing upward in the thickness direction z) and the electrode 513 disposed on the lower surface (the surface facing downward in the thickness direction z). The first chip 51 is bonded to the first pad part 41 with a conductive bonding material such as solder, for example, and the electrode 513 provided on the lower surface electrically conducts to the first pad part 41 via the conductive bonding material.

As shown in FIG. 14, the second chip 52 has three electrodes 521, 522 and 523. In the example in which the second chip 52 is an IGBT, the electrode 521 is a gate, the electrode 522 is an emitter, and the electrode 523 is a collector. The second chip 52 is configured, for example, as a vertical structure type, with two electrodes 521 and 522 disposed on the upper surface (the surface facing upward in the thickness direction z) and the electrode 523 disposed on the lower surface (the surface facing downward in the thickness direction z). The second chip 52 is bonded to the second pad part 42 with a conductive bonding material such as solder, for example, and the electrode 523 provided on the lower surface electrically conducts to the second pad part 42 via the conductive bonding material.

The first chip 51 and the second chip 52 may have a horizontal structure rather than a vertical structure. In this case, the electrode 513 is disposed on the upper surface of the first chip 51, and the electrode 523 is disposed on the upper surface of the second chip 52. Thus, the electrode 513 and the first pad part 41 (or the first extension part 31) are electrically connected with a bonding wire or a metal plate, while the electrode 523 and the second pad part 42 (or the fourth extension part 34 or the fifth extension part 35) are electrically connected with a bonding wire or a metal plate.

In the electronic device A4, the connecting member 61 is bonded to the electrode 511 and the third extension part 33 of one of the third leads 13 to electrically connect these. The third mount portion 231 of the third lead 13 to which the connecting member 61 is bonded is a signal input terminal for inputting a drive signal for the first chip 51. The connecting members 62 are bonded to the electrode 512 and the second pad part 42 to electrically connect these. The connecting member 63 is bonded to the electrode 512 and the third extension part 33 of one of the third leads 13 to electrically connect these. The third mount portion 231 of the third lead 13 to which the connecting member 63 is bonded is a detection terminal for detecting the current flowing in the first chip 51. The connecting member 64 is bonded to the electrode 521 and the third extension part 33 of one of the third leads 13 to electrically connect these. The third mount portion 231 of the third lead 13 to which the connecting member 64 is bonded is a signal input terminal for inputting a drive signal for the second chip 52. The connecting members 65 are bonded to the electrode 522 and the second extension part 32 of the second lead 12 to electrically connect these. The connecting member 66 is bonded to the electrode 522 and the third extension part 33 of one of the third leads 13 to electrically connect these. The third mount portion 231 of the third lead 13 to which the connecting member 66 is bonded is a detection terminal for detecting the current flowing in the second chip 52.

In the electronic device A4, a power supply voltage (e.g., DC voltage) is applied to the first terminal part 21 and the second terminal part 22, and the power supply voltage is converted into a predetermined voltage (e.g., AC voltage) by the switching operation of each of the first chip 51 and the second chip 52. The converted voltage is outputted from the fourth terminal part 24 and the fifth terminal part 25.

As with the electronic devices A1, the electronic device A4 is capable of suppressing electric discharge between the first terminal part 21 and the second terminal part 22 while achieving downsizing of the device. Also, as with the electronic device A1, the electronic device A4 is capable of relieving the stress applied to the first terminal part 21 and the second terminal part 22, thereby improving the mounting reliability of the device.

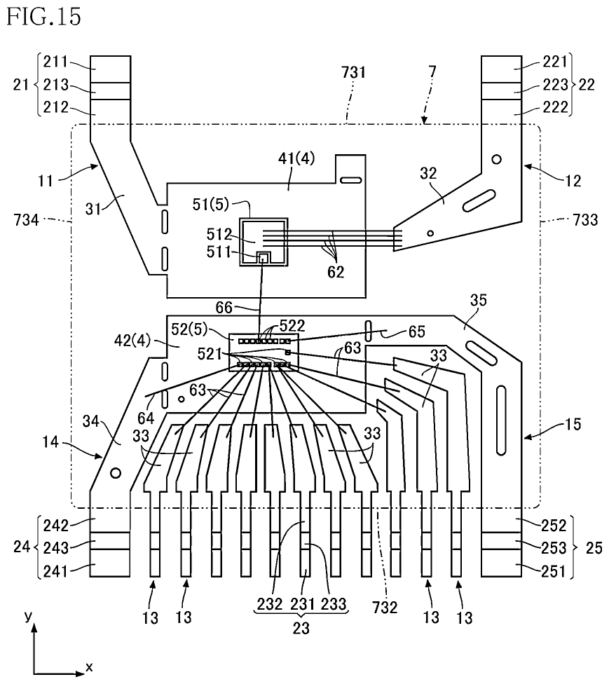

The electronic device A4 shows an example where the first chip 51 and the second chip 52 are both switching elements. Unlike this example, as shown in FIG. 15, the second chip 52 may be a control IC that controls the drive of the first chip 51, rather than a switching element. This variation achieves the same effect as the electronic device A4.

As will be understood from the third variation, the function of the electronic component 5 in the electronic device of the present disclosure is not limited to voltage detection. Additionally, in the electronic device of the present disclosure, the electronic component 5 (the first chip 51 and the second chip 52) includes semiconductor elements made of semiconductor materials.

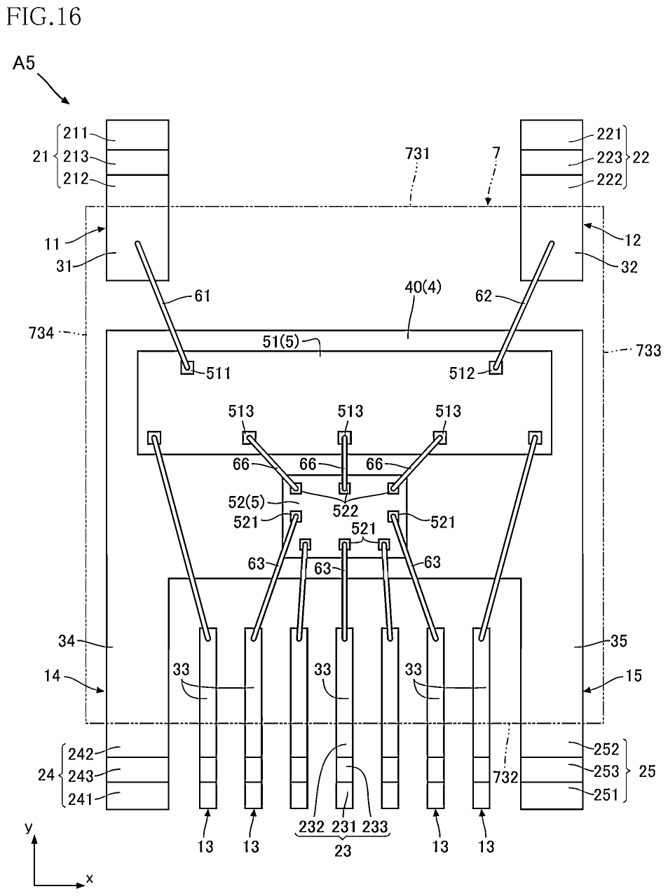

FIG. 16 shows an electronic device A5 according to a fourth variation. As will be understood from FIG. 16, the electronic device A5 differs from the electronic device A1 in that the first chip 51 and the second chip 52 are mounted on a single pad part (the pad part 40, described later).

In the electronic device A5, the die pad 4 includes a single pad part 40. The first chip 51 and the second chip 52 are mounted on the pad part 40. In the illustrated example, the pad part 40 (die pad 4) is spaced apart from the first lead 11, the second lead 12, and the third leads 13, and connected to the fourth lead 14 and the fifth lead 15.

As with the electronic devices A1, the electronic device A5 is capable of suppressing electric discharge between the first terminal part 21 and the second terminal part 22 while achieving downsizing of the device. Also, as with the electronic device A1, the electronic device A5 is capable of relieving the stress applied to the first terminal part 21 and the second terminal part 22, thereby improving the mounting reliability of the device.

As will be understood from the fourth variation, the die pad 4 in the electronic device of the present disclosure is not limited to the configuration including the first pad part 41 and the second pad part 42. That is, in the electronic device of the present disclosure, there is no limitation on whether the die pad 4 is divided into a plurality of pad parts or not.

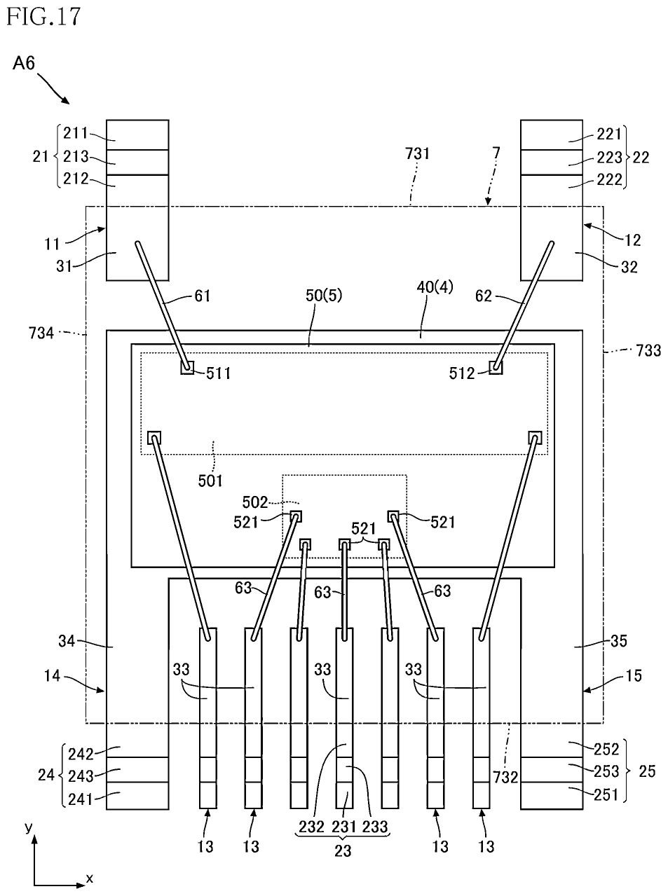

FIG. 17 shows an electronic device A6 according to a fifth variation. The electronic device A6 differs from the electronic device A5 in that the electronic component 5 consists of one chip 50.

The chip 50 includes, for example, a first functional part 501 and a second functional part 502. That is, the first functional part 501 and the second functional part 502 are integrated into the single chip 50. The function of each of the first functional part 501 and the second functional part 502 is not limited. In one example, the first functional part 501 has the function of outputting a signal corresponding to the potential of the first terminal part 21 and a signal corresponding to the potential of the second terminal part 22 as with the first chip 51 of the electronic device A1. The second functional part 502 has the function of outputting a signal corresponding to the potential difference between the first terminal part 21 and the second terminal part 22 as with the second chip 52 of the electronic device A1. Unlike this configuration, the first functional part 501 may have a switching function as with the first chip 51 of the electronic device A3, and the second functional part 502 may have a switching function as with the second chip 52 of the electronic device A3. The first functional part 501 and the second functional part 502 electrically conduct to each other via an internal wiring (not shown) of the chip 50, for example.

As with the electronic devices A1, the electronic device A6 is capable of suppressing electric discharge between the first terminal part 21 and the second terminal part 22. Also, as with the electronic device A1, the electronic device A6 is capable of relieving the stress applied to the first terminal part 21 and the second terminal part 22, thereby improving the mounting reliability of the device.

As will be understood from the fifth variation, the electronic component 5 in the electronic device of the present disclosure is not limited to the configuration including the first chip 51 and the second chip 52. That is, in the electronic device of the present disclosure, there is no limitation on whether the electronic component 5 includes a plurality of chips or not.

The electronic device according to the present disclosure is not limited to the above-described embodiments. Various modifications in design may be made freely in the specific structure of each part of the electronic device according to the present disclosure. The present disclosure includes the embodiments described in the following clauses.

### Clause 1.

An electronic device comprising:
an electronic component;
a sealing resin covering the electronic component;
a first terminal part protruding from the sealing resin toward a first side in a first direction orthogonal to a thickness direction of the sealing resin;
a second terminal part protruding from the sealing resin toward the first side in the first direction; and
a plurality of third terminal parts each protruding from the sealing resin toward a second side in the first direction, wherein
the first terminal part and the second terminal part are located side by side with a first interval in a second direction orthogonal to the thickness direction and the first direction,
the plurality of third terminal parts are arranged in the second direction with a second interval,
the first interval is greater than the second interval,
the first terminal part includes a first mount portion located at an end opposite to the sealing resin in the first direction,
the second terminal part includes a second mount portion located at an end opposite to the sealing resin in the first direction,
each of the plurality of third terminal parts includes a third mount portion located at an end opposite to the sealing resin in the first direction, and
a first dimension along the second direction of the first mount portion and a second dimension along the second direction of the second mount portion are each greater than a third dimension along the second direction of respective third mount portions of the plurality of third terminal parts.

### Clause 2.

The electronic device according to clause 1, wherein the first dimension and the second dimension are 1 to 10 times the third dimension.

### Clause 3.

The electronic device according to clause 1 or 2, wherein the first terminal part includes a first root portion located at an end closer to the sealing resin in the first direction and connected to the first mount portion, and
a dimension along the second direction of the first root portion is equal to the first dimension.

### Clause 4.

The electronic device according to clause 3, wherein the second terminal part includes a second root portion located at an end closer to the sealing resin in the first direction and connected to the second mount portion, and
a dimension along the second direction of the second root portion is equal to the second dimension.

### Clause 5.

The electronic device according to any one of clauses 1 to 4, wherein the first interval is 10 to 20 times the second interval.

### Clause 6.

The electronic device according to any one of clauses 1 to 5, further comprising a fourth terminal part and a fifth terminal part that protrude from the sealing resin toward the second side in the first direction and that are disposed on respective sides in the second direction of the plurality of third terminal parts, wherein
the fourth terminal part overlaps with the first terminal part as viewed in the first direction, and
the fifth terminal part overlaps with the second terminal part as viewed in the first direction.

### Clause 7.

The electronic device according to clause 6, wherein the fourth terminal part includes a fourth mount portion located at an end opposite to the sealing resin in the first direction, and
a fourth dimension along the second direction of the fourth mount portion is equal to the first dimension.

### Clause 8.

The electronic device according to clause 6 or 7, wherein the fifth terminal part includes a fifth mount portion located at an end opposite to the sealing resin in the first direction, and
a fifth dimension along the second direction of the fifth mount portion is equal to the second dimension.

### Clause 9.

The electronic device according to any one of clauses 1 to 8, further comprising a first pad part and a second pad part spaced apart from each other and covered with the sealing resin,
wherein the electronic component includes a first chip mounted on the first pad part and a second chip mounted on the second pad part.

### Clause 10.

The electronic device according to clause 9, wherein the first chip electrically conducts to each of the first terminal part and the second terminal part, and
the second chip electrically conducts to at least one of the plurality of third terminal parts.

### Clause 11.

The electronic device according to clause 10, further comprising:
a first extension part extending from the first terminal part; and
a second extension part extending from the second terminal part,
wherein the first extension part and the second extension part are covered with the sealing resin.

### Clause 12.

The electronic device according to clause 11, wherein the first extension part is connected to the first pad part, and
the second extension part is spaced apart from the first pad part.

### Clause 13.

The electronic device according to clause 11 or 12, further comprising a plurality of third extension parts extending from the plurality of third terminal parts, respectively, wherein
the plurality of third extension parts are covered with the sealing resin.

### Clause 14.

The electronic device according to any one of clauses 9 to 13, wherein the first chip includes a resistor element and outputs a first signal corresponding to a potential at the first terminal part and a second signal corresponding to a potential at the second terminal part, and
the second chip includes an operational amplifier, receives the first signal and the second signal, and outputs a third signal corresponding to a potential difference between the first terminal part and the second terminal part.

REFERENCE NUMERALS

| | |
|---|---|
| A1 to A6: Electronic device | 11: First lead |
| 12: Second lead | 13: Third lead |
| 14: Fourth lead | 15: Fifth lead |
| 21: First terminal part | 211: First mount portion |
| 212: First root portion | 213: First intermediate portion |
| 22: Second terminal part | 221: Second mount portion |
| 222: Second root portion | 223: Second intermediate portion |
| 23: Third terminal part | 231: Third mount portion |
| 232: Third root portion | 233: Third intermediate portion |
| 24: Fourth terminal part | 241: Fourth mount portion |
| 242: Fourth root portion | 243: Fourth intermediate portion |
| 25: Fifth terminal part | 251: Fifth mount portion |
| 252: Fifth root portion | 253: Fifth intermediate portion |
| 31: First extension part | 32: Second extension part |
| 33: Third extension part | 34: Fourth extension part |
| 341: Branching portion | 35: Fifth extension part |
| 351: Branching portion | 4: Die pad |
| 40: Pad part | 41: First pad part |
| 42: Second pad part | 5: Electronic component |
| 50: Chip | 501: First functional part |
| 502: Second functional part | 51: First chip |
| 511 to 513: Electrode | 52: Second chip |
| 521 to 523: Electrode | 61 to 66: Connecting member |
| 7: Sealing resin | 71: Resin obverse surface |
| 72: Resin reverse surface | 731 to 734: Resin side surface |
| OP: Operational amplifier | R1 to R5: Resistor element |
| T1, T2: Terminal | |

1. An electronic device comprising:
an electronic component;
a sealing resin covering the electronic component;
a first terminal part protruding from the sealing resin toward a first side in a first direction orthogonal to a thickness direction of the sealing resin;
a second terminal part protruding from the sealing resin toward the first side in the first direction; and
a plurality of third terminal parts each protruding from the sealing resin toward a second side in the first direction, wherein
the first terminal part and the second terminal part are located side by side with a first interval in a second direction orthogonal to the thickness direction and the first direction,
the plurality of third terminal parts are arranged in the second direction with a second interval,
the first interval is greater than the second interval,
the first terminal part includes a first mount portion located at an end opposite to the sealing resin in the first direction,
the second terminal part includes a second mount portion located at an end opposite to the sealing resin in the first direction,
each of the plurality of third terminal parts includes a third mount portion located at an end opposite to the sealing resin in the first direction, and
a first dimension along the second direction of the first mount portion and a second dimension along the second direction of the second mount portion are each greater than a third dimension along the second direction of respective third mount portions of the plurality of third terminal parts.

2. The electronic device according to claim 1, wherein the first dimension and the second dimension are 1 to 10 times the third dimension.

3. The electronic device according to claim 1, wherein the first terminal part includes a first root portion located at an end closer to the sealing resin in the first direction and connected to the first mount portion, and
a dimension along the second direction of the first root portion is equal to the first dimension.

4. The electronic device according to claim 3, wherein the second terminal part includes a second root portion located at an end closer to the sealing resin in the first direction and connected to the second mount portion, and
a dimension along the second direction of the second root portion is equal to the second dimension.

5. The electronic device according to claim 1, wherein the first interval is 10 to 20 times the second interval.

6. The electronic device according to claim 1, further comprising a fourth terminal part and a fifth terminal part that protrude from the sealing resin toward the second side in the first direction and that are disposed on respective sides in the second direction of the plurality of third terminal parts, wherein
the fourth terminal part overlaps with the first terminal part as viewed in the first direction, and
the fifth terminal part overlaps with the second terminal part as viewed in the first direction.

7. The electronic device according to claim 6, wherein the fourth terminal part includes a fourth mount portion located at an end opposite to the sealing resin in the first direction, and
a fourth dimension along the second direction of the fourth mount portion is equal to the first dimension.

8. The electronic device according to claim 6, wherein the fifth terminal part includes a fifth mount portion located at an end opposite to the sealing resin in the first direction, and
a fifth dimension along the second direction of the fifth mount portion is equal to the second dimension.

9. The electronic device according to claim 1, further comprising a first pad part and a second pad part spaced apart from each other and covered with the sealing resin,
wherein the electronic component includes a first chip mounted on the first pad part and a second chip mounted on the second pad part.

10. The electronic device according to claim 9, wherein the first chip electrically conducts to each of the first terminal part and the second terminal part, and
the second chip electrically conducts to at least one of the plurality of third terminal parts.

11. The electronic device according to claim 10, further comprising:
a first extension part extending from the first terminal part; and
a second extension part extending from the second terminal part,
wherein the first extension part and the second extension part are covered with the sealing resin.

12. The electronic device according to claim 11, wherein the first extension part is connected to the first pad part, and
the second extension part is spaced apart from the first pad part.

13. The electronic device according to claim 11, further comprising a plurality of third extension parts extending from the plurality of third terminal parts, respectively, wherein
the plurality of third extension parts are covered with the sealing resin.

14. The electronic device according to claim 9, wherein the first chip includes a resistor element and outputs a first signal corresponding to a potential at the first terminal part and a second signal corresponding to a potential at the second terminal part, and
the second chip includes an operational amplifier, receives the first signal and the second signal, and outputs a third signal corresponding to a potential difference between the first terminal part and the second terminal part.
